(19) United States
(12) Patent Application Publication
(10) Pub. No.: US 2006/0176980 A1
(43) Pub. Date: Aug. 10, 2006

(54) Symbol timing recovery apparatus usable with VSB receiver and method thereof

(76) Inventor: Dong-hoon Lee, Suwon-si (KR)

Correspondence Address: STANZIONE & KIM, LLP, 919 18TH STREET, N.W., SUITE 440, WASHINGTON, DC, 20006, US

(21) Appl. No.: 11/347,274

(22) Filed: Feb. 6, 2006

(30) Foreign Application Priority Data
Feb. 7, 2005 (KR) 2005-11401

(51) Int. Cl. H03D 1/24; H04L 27/22

(52) U.S. Cl. 375/321; 375/326

(57) ABSTRACT

A symbol timing recovery apparatus usable with a VSB receiver, includes a first correlator to calculate a first correlation value between an I channel receiving signal and a timing recovery reference signal, a second correlator to calculate a second correlation value between a Q channel receiving signal having a phase difference of 90° with respect to the I channel receiving signal and the reference signal, a calculating member to calculate a non-coherent combining value based on the first correlation value output from the first correlator and the second correlation value output from the second correlator, an early-late subtractor to calculate a difference value between the non-coherent combing value of a previous sample and the non-coherent combing value of a subsequent sample in samples of the I and Q channel receiving signals, and to detect a symbol timing offset based on the calculated difference signal, and a symbol timing controller to control symbol timing based on the detected symbol timing offset. Accordingly, by using the non-coherent combining value of the first and second correlation values, it is possible to perform the symbol timing recovery regardless of carrier recovery error, thereby minimizing symbol timing jitter.

### CROSS-REFERENCE TO RELATED APPLICATIONS

This application claims benefit under 35 U.S.C. § 119 from Korean Patent Application No. 2005-11401, filed on Feb. 7, 2005, in the Korean Patent Office, the disclosure of which is incorporated herein in its entirety.

### BACKGROUND OF THE INVENTION

1. Field of the Invention

The present general inventive concept relates to a symbol timing recovery apparatus usable with a VSB receiver and method thereof, and more particularly, to a symbol timing recovery apparatus which usable with a VSB to recover symbol timing based on non-coherent combining of correlation values calculated using both an I channel receiving signal and a Q channel receiving signal.

2. Description of the Related Art

In order to demodulate data in a data receiver device for receiving data transmitted by the Vestigial Side Band (VSB) signal modulation scheme, it is necessary to minimize the frequency offset and the phase noise generated by an RF oscillator or a tuner when a signal is received. Such a process is called carrier recovery.

The process to generate the same clocks which are used in the transmitting apparatus in a receiver to receive correct data is called symbol timing recovery.

In a digital broadcasting system using the VSB modulation scheme of the Advanced Television Systems Committee (ATSC) which is a standard for U.S. digital television, a pilot signal which exists in the transmitting signal is used as a synchronous signal of a carrier. The pilot signal functions as a signal accompanying the carrier transmitted to correctly recover the carrier.

As methods of recovering the symbol timing, there is a method using a data segment synchronous signal regularly inserted by a sending device, and a method using a BECM (Band Edge Component Maximization) algorithm.

FIG. 1 illustrates a frequency spectrum of a conventional VSB signal including a pilot signal.

Referring to FIG. 1, in the frequency spectrum of the conventional VSB signal having the pilot signal, a region a is an upper frequency band of the VSB signal and is used for a BECM algorithm, and a region b indicates the pilot signal.

FIG. 2 is a block diagram illustrating a conventional symbol timing recovery apparatus for a VSB receiver.

Referring to FIG. 2, the conventional symbol timing recovery apparatus has an analog to digital converter (ADC) 10, a pre-filter 20, BECM portion 30, a loop filter 40, and an NCO (Numerically Controlled Oscillator) 50. The ADC 10 converts the VSB signal to a digital signal. The pre-filter 20 allows only the upper frequency band of the converted VSB signal to be passed. That is, the pre-filter 20 allows only signals in the region a of FIG. 1 to be passed.

The BECM portion 30 extracts the error information of a symbol clock from the VSB signal. More specifically, The BECM portion 30 obtains the phase information of the symbol clock by using a spectral line as a harmonic signal of the upper frequency band of the VSB modulated signal to the received signal.

The loop filter 40 outputs an NCO control voltage corresponding to the error information of the BECM portion 30. The loop filter 40 may be a 1st order loop or a 2nd order loop based on whether only the frequency offset is to be corrected or both the frequency offset and the phase offset are to be corrected, in which a coefficient value thereof is variable depending on the conversion step.

In the NCO 50, the phase information of the symbol clock obtained at BECM portion 30 is converted into a frequency component to be used as the sampling clock of the ADC 10. The NCO 50 may be changed to a VCXO in an analog circuit.

Such a conventional symbol timing recovery apparatus operates repeatedly in a shape of a closed loop, as illustrated in FIG. 2, until the phase error becomes zero.

FIG. 3 is a block diagram illustrating an example the BECM portion 30 of FIG. 2.

Referring to FIG. 3, the BECM portion 30 has a non-linear device 31, a symbol tone extractor 33, and a phase detector 35.

The non-linear device 31 receives signals of the upper frequency band of the VSB modulation signal filtered by the pre-filter 20 and generates the harmonic components of the upper frequency band.

The symbol tone extractor 33 extracts the symbol tone as a component having the same frequency as the clock used at the transmitting apparatus among the harmonic components generated by the non-linear device 31. The phase detector 35 outputs the error information of the symbol clock or the error information of a symbol phase based on a reference symbol phase which is preliminarily set using the extracted symbol tone and an extracted symbol tone phase.

FIG. 4 is a diagram illustrating a BECM circuit which uses a square multiplier as the non-linear device 31 of FIG. 3.

Typical examples of the non-linear device 31 include a square multiplier, a fourth power multiplier, and an absolute value circuit, etc., in which the Gardner method is used. As illustrated in FIG. 4, the BECM circuit using the square multiplier is used as the non linear device 31 of the BECM portion 30.

However, in the conventional symbol timing recovery apparatus using the upper band of the received signals, if the upper band is damaged, performance of the apparatus deteriorates. Particularly, as multiple path components are in large quantities, the upper band is likely to be damaged. As a result, in the receiver, it is not possible to accurately recover the data clock, thereby deteriorating the receiving performance. Moreover, when an algorithm of a BECM group is employed in the VSB type receiver, since a recovery of a carrier affects the recovery performance of the symbol timing, undesirable jitter increases.

### SUMMARY OF THE INVENTION

Accordingly, the present general inventive concept provides a symbol timing recovery apparatus usable with a VSB receiver and a method thereof which recover symbol timing independently of a carrier recovery error by performing symbol timing recovery based on non-coherent combining of correlation values calculated using both an I channel receiving signal and a Q channel receiving signal to minimize jitter.

The present general inventive concept also provides a symbol timing recovery apparatus and a method thereof which reduce a time required to perform a synchronization by eliminating the carrier recovery error while the symbol timing recovery is performed, i.e., by using non-coherent combining of correlation values of a receiving signal and a reference signal to simultaneously perform the carrier recovery and the symbol timing.

The present general inventive concept also provides a symbol timing recovery apparatus usable with a VSB receiver and a method thereof in which a recovery of symbol timing is performed by a reference signal such that the symbol timing is recovered even if an upper band of a received signal is damaged.

Additional aspects and utilities of the present general inventive concept will be set forth in part in the description which follows and, in part, will be obvious from the description, or may be learned by practice of the general inventive concept.

The foregoing and/or other aspects of the present general inventive concept are achieved by providing a symbol timing recovery apparatus usable with a VSB receiver, including a first correlator to calculate a first correlation value between an I channel receiving signal and a timing recovery reference signal, a second correlator to calculate a second correlation value between a Q channel receiving signal having a phase difference of 90° with respect to the I channel receiving signal and the reference signal, a calculating member to calculate a non-coherent combining value based on the first correlation value calculated by the first correlator and the second correlation value calculated by the second correlator, an early-late subtractor to calculate a difference value between the non-coherent combining value of a previous sample and the non-coherent combining value of a subsequent sample in samples of the I and Q channel receiving signals, and to detect a symbol timing offset based on the calculated difference value, and a symbol timing controller to control symbol timing based on the detected symbol timing offset.

The timing recovery reference signal can include at least one of a segment sync signal and a field sync signal.

The first correlator and the second correlator may each include a finite impulse filter.

The calculating member may calculate the non-coherent combining value based on the first correlation value and the second correlation value according to the following Equation:

$$S = {\vert {\sum }_{k = 0}^{M - 1} {r}_{i} ( k ) p ( k ) \vert}^{2} + {\vert {\sum }_{k = 0}^{M - 1} {r}_{Q} ( k ) p ( k ) \vert}^{2}$$

wherein S is the non-coherent combining value output by the calculator, M is a correlation length, r_{I}(k) is the I channel receiving signal, r_{Q}(k) is the Q channel receiving signal, and p(k) is the timing recovery reference signal.

The early-late subtractor may detect the symbol timing offset based on the following Equation:

$$\hat{τ} = {S}_{early} - {S}_{late} = \{ {\vert {\sum }_{k = 0}^{M - 1} {r}_{I} ( k ) p ( k + Δ ) \vert}^{2} + {\vert {\sum }_{k = 0}^{M - 1} {r}_{Q} ( k ) p ( k + Δ ) \vert}^{2} \} - \{ {\vert {\sum }_{k = 0}^{M - 1} {r}_{I} ( k ) p ( k - Δ ) \vert}^{2} + {\vert {\sum }_{k = 0}^{M - 1} {r}_{Q} ( k ) p ( k - Δ ) \vert}^{2} \}$$

wherein, \hat{τ} is the detected symbol timing offset, S_{early} is the non-coherent combining value of the previous sample calculated by the calculating member, Sₗₐₜₑ is the non-coherent combining value of the subsequent sample calculated by the calculating member, M is a correlation length, r_{I}(k) is the I channel receiving signal, r_{Q}(k) is the Q channel receiving signal, p(k) is the timing recovery reference signal, and Δ is a phase difference between the I and Q receiving signals and the timing recovery reference signal.

The phase difference between the I and Q receiving signals and the timing recovery reference signal may be one of a half of symbol period and a symbol period.

The foregoing and/or other aspects of the present general inventive concept are also achieved by providing a symbol timing recovery apparatus usable with a VSB receiver, comprising a correlation unit to receive an input signal including an I channel signal and a Q channel signal having a phase difference of 90° with respect to the I channel signal, to calculate a first correlation value between the I channel signal and a reference signal and a second correlation value between the Q channel signal and the reference signal for each of a plurality of samples of the input signal, a calculating unit to calculate a symbol timing offset corresponding to one of the plurality of samples, based on a difference between a non-coherent combination of the first and second correlation values of a previous sample and a non-coherent combination of the first and second correlation values of a next sample, and a control unit to control symbol timing of the input signal based on the calculated symbol timing offset.

The foregoing and/or other aspects of the present general inventive concept are also achieved by providing a symbol timing recovery method of a VSB receiver, including calculating a first correlation value between an I channel receiving signal and a timing recovery reference signal and a second correlation value between a Q channel receiving signal having a phase difference of 90° with respect to the I channel receiving signal and the timing recovery reference signal, calculating a non-coherent combining value based on the first and the second correlation values, calculating a difference value between the non-coherent combining value of a previous sample and the non-coherent combining value of a subsequent sample in samples of the I and Q channel receiving signals to detect a symbol timing offset, and controlling the symbol timing based on the detected symbol timing offset.

The timing recovery reference signal may include at least one of a segment sync signal and a field sync signal.

The calculating of the first correlation value and the second correlation value may include calculating the first and second correlation values using a FIR filter (Finite Impulse Response filter).

The calculating of the non-coherent combining value based on the first and the second correlation values may include calculating the non-coherent combining value according to the following Equation:

$$S = {\vert {\sum }_{k = 0}^{M - 1} {r}_{I} ( k ) p ( k ) \vert}^{2} + {\vert {\sum }_{k = 0}^{M - 1} {r}_{Q} ( k ) p ( k ) \vert}^{2}$$

wherein S is the non-coherent combining value of the first and the second correlation values, M is a correlation length, r_{I}(k) is the I channel receiving signal, r_{Q}(k) is the Q channel receiving signal, and p(k) is the timing recovery reference signal.

The calculating of the difference value between the non-coherent combining value of the previous sample and the non-coherent combining value of the subsequent sample to detect the symbol timing offset may include detecting the symbol timing offset based on the following Equation:

$$\hat{τ} = {S}_{early} - {S}_{late} = \{ {\vert {\sum }_{k = 0}^{M - 1} {r}_{I} ( k ) p ( k + Δ ) \vert}^{2} + {\vert {\sum }_{k = 0}^{M - 1} {r}_{Q} ( k ) p ( k + Δ ) \vert}^{2} \} - \{ {\vert {\sum }_{k = 0}^{M - 1} {r}_{I} ( k ) p ( k - Δ ) \vert}^{2} + {\vert {\sum }_{k = 0}^{M - 1} {r}_{Q} ( k ) p ( k - Δ ) \vert}^{2} \}$$

wherein, \hat{τ} is the symbol timing offset, S_{early} is the non-coherent combining value of the previous sample, Sₗₐₜₑ is the non-coherent combining value of the subsequent sample, M is a correlation length, r_{I}(k) is the I channel receiving signal, r_{Q}(k) is the Q channel receiving signal, p(k) is the timing recovery reference signal, and Δ is a phase difference between the I and Q receiving signals and the timing recovery reference signal.

The phase difference between the I and Q receiving signals and the timing recovery reference signal may be one of a half of symbol period and a symbol period.

The foregoing and/or other aspects of the present general inventive concept are also achieved by providing a symbol timing recovery method, including sampling an input signal including an I channel signal and a Q channel signal having a phase difference of 90° with respect to the I channel signal, calculating a first correlation value between the I channel signal and a reference signal and a second correlation value between the Q channel signal and the reference value for each sample of the input signal, calculating a symbol timing offset corresponding to one of the samples of the input signal based on a difference between a non-coherent combination of the first and second correlation values of a previous sample and a non-coherent combination of the first and second correlation values of a subsequent sample, and controlling symbol timing based on the calculated symbol timing offset.

The foregoing and/or other aspects of the present general inventive concept are also achieved by providing a symbol timing recovery apparatus, including a first correlator to calculate a first correlation value between an I channel receiving signal and a timing recovery reference signal, a second correlator to calculate a correlation between a Q channel receiving signal having a phase difference of 90° with respect to the I channel receiving signal and the timing recovery reference signal, a calculating member to calculate a non-coherent combining value based on the first correlation value output from the first correlator and the second correlation value output from the second correlator; an early-late subtractor to calculate a difference value between the non-coherent combining value of a previous sample calculated by the calculating member and the non-coherent combining value of a subsequent sample calculated by the calculating member in samples of the I and Q channel receiving signals, and to detect a symbol timing offset based on the calculated difference value, and a symbol timing controller to control symbol timing based on the symbol timing offset.

### BRIEF DESCRIPTION OF THE DRAWINGS

These and/or other aspects of the present general inventive concept will become apparent and more readily appreciated from the following description of the embodiments, taken in conjunction with the accompanying drawings of which:

FIG. 1 is a diagram illustrating a frequency spectrum of a VSB signal including a pilot signal.

FIG. 2 is a block diagram illustrating a conventional symbol timing recovery apparatus for a VSB receiver

FIG. 3 is a block diagram illustrating an example of a BECM portion of the conventional symbol timing recovery apparatus of FIG. 2.

FIG. 4 is a diagram illustrating a BCM circuit which uses a square multiplier as a non-linear device of the BECM portion of FIG. 3.

FIG. 5 is a block diagram illustrating a symbol timing recovery apparatus usable with a VSB receiver according to an embodiment of the present general inventive concept.

FIG. 6 is a flow chart illustrating a symbol timing recovery method of a VSB receiver according to an embodiment of the present general inventive concept.

FIG. 7 is a diagram illustrating a characteristic curve of an early-late subtractor of the symbol timing recovery apparatus of FIG. 5.

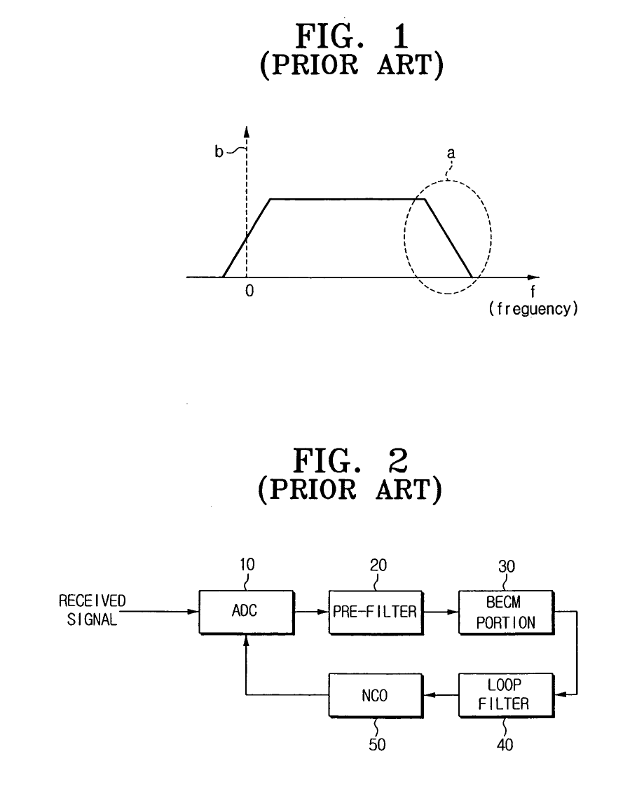

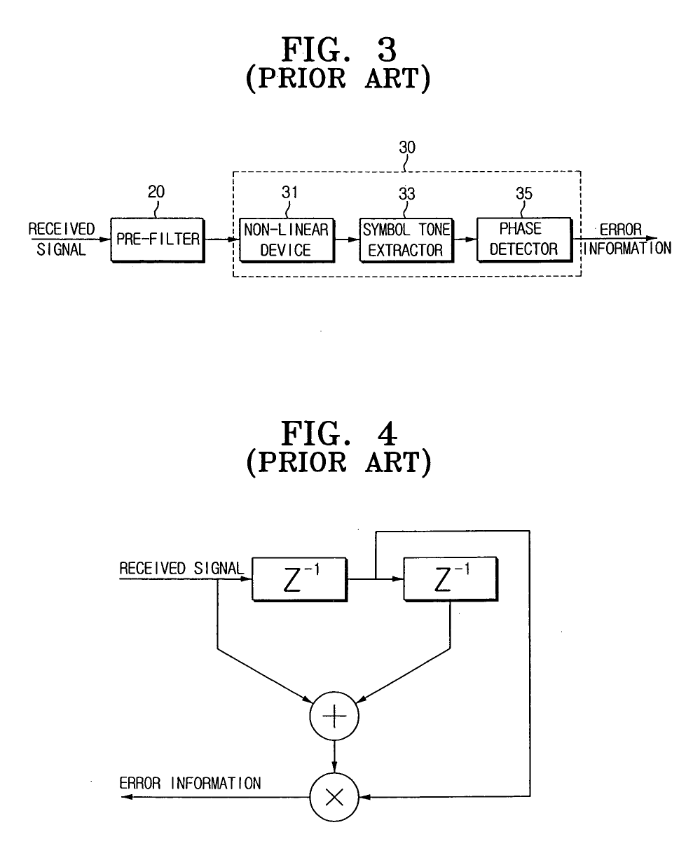

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

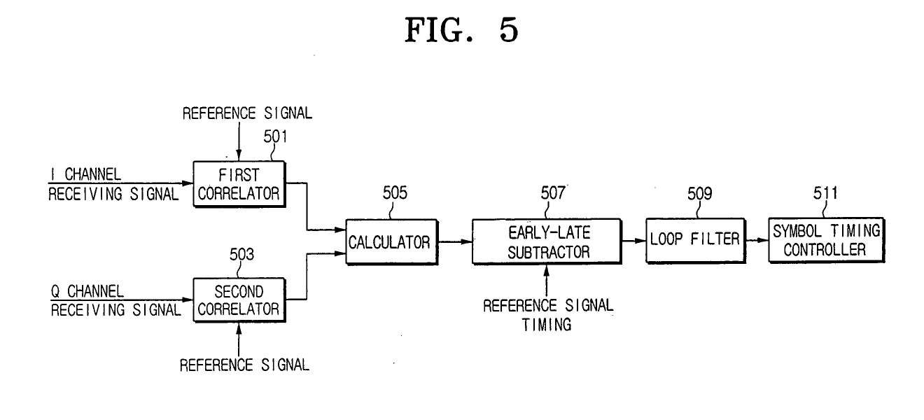

FIG. 5 is a block diagram illustrating a symbol timing recovery apparatus usable with a VSB receiver according to an embodiment of the present general inventive concept.

Referring to FIG. 5, the symbol timing recovery apparatus includes a first correlator 501, a second correlator 503, a calculator 505, an early-late subtractor 507, a loop filter 509, and a symbol timing controller 511. The symbol timing recovery apparatus performs a symbol timing recovery process using samples of an input signal. The input signal includes an I channel receiving signal and a Q channel receiving signal.

The first correlator 501 calculates a correlation between each sample of the I channel receiving signal carrying transmission data and a reference signal and outputs a first correlation value. The reference signal acts as a signal to detect a symbol timing and may be a segment sync signal or a field sync signal. The first correlation value can be a sum of correlation values between the I channel receiving signal and the reference signal over a predetermined correlation length.

The second correlator 503 calculates a correlation between each sample of the Q channel receiving signal and the reference signal and outputs a second correlation value. The Q channel receiving signal can be in the form of a so called “Hilbert transform” of the I channel receiving signal, and has a phase difference of 90° from the I channel receiving signal. The first correlator 501 and the second correlator 503 may each be an FIR (finite impulse response) filter having an active correlator form. The second correlation value can be a sum of correlation values between the Q channel receiving signal and the reference signal over the predetermined correlation length.

The calculator 505 calculates a non-coherent combining value of each sample with respect to the output first and second correlation values of the first correlator 501 and the second correlator 503. That is, the calculator 505 squares the first correlation values, squares the second correlation values, and adds the squared first and second correlation values together to calculate the non-coherent combining value. Therefore, the calculator 505 can be realized by first and second square multipliers to respectively square the first and second correlation values and an adder to add each of output values of the first and second square multipliers. Here, the non-coherent combining value output by the calculator 505 can be expressed by the following Equation 1:

$$S = {\vert {\sum }_{k = 0}^{M - 1} {r}_{I} ( k ) p ( k ) \vert}^{2} + {\vert {\sum }_{k = 0}^{M - 1} {r}_{Q} ( k ) p ( k ) \vert}^{2} \qquad ( Equation 1 )$$

wherein S is the non-coherent combining value output by the calculator, M is the correlation length, r_{I}(k) is the I channel receiving signal, r_{Q}(k) is the Q channel receiving signal, and p(k) is the reference signal.

The early-late subtractor 507 calculates a symbol timing offset of a current sample by calculating a difference value between a previous non-coherent combining value output by the calculator 505 and a subsequent non-coherent combining value output by the calculator 505. The previous and subsequent non-coherent combing values refer to the non-coherent combining values of previous and subsequent samples of the input signal. That is, the early-late subtractor 507 calculates the difference value between the non-coherent combining value calculated with respect to the first and second correlation values of the reference signal and a previous sample of the input signal, and the non-coherent combining value calculated with respect to the first and second correlation values of the reference signal and a subsequent sample of the input signal. Thus, the symbol timing offset output by the early-late subtractor 507 can be expressed by the following Equation 2:
\hat{τ}=S_{early}−Sₗₐₜₑ (Equation 2)

wherein \hat{τ} is the difference value output by the early-late subtractor 507 and corresponds to the symbol timing offset of the current sample, S_{early} is the non-coherent combining value of the previous sample, and Sₗₐₜₑ is the non-coherent combining value of the subsequent sample.

Here, the non-coherent combining value of the previous sample and the non-coherent combining value of the subsequent sample can be expressed by the following Equations 3 and 4, respectively:

$$\begin{matrix}{S}_{early} = {\vert {\sum }_{k = 0}^{M - 1} {r}_{I} ( k ) p ( k + Δ ) \vert}^{2} + {\vert {\sum }_{k = 0}^{M - 1} {r}_{Q} ( k ) p ( k + Δ ) \vert}^{2} & ( Equation 3 ) \\ {S}_{late} = {\vert {\sum }_{k = 0}^{M - 1} {r}_{I} ( k ) p ( k - Δ ) \vert}^{2} + {\vert {\sum }_{k = 0}^{M - 1} {r}_{Q} ( k ) p ( k - Δ ) \vert}^{2} & ( Equation 4 )\end{matrix}$$

wherein S_{early} is the non-coherent combining value of the previous sample, Sₗₐₜₑ is the non-coherent combining value of subsequent sample, M is the correlation length, r_{I}(k) is the I channel receiving signal, r_{Q}(k) is the Q channel receiving signal, p(k) is the reference signal, and Δ is a phase difference between the receiving signal and the reference signal. A symbol period Tₛ or a half Tₛ/2 of the symbol period Ts can be used as the value of the phase difference Δ. Thus, timings of the previous sample and the subsequent sample can be ±Tₛ or ±Tₛ/2 before and after the present sample.

As illustrated in Equations 3 and 4, the non-coherent combining values output by the calculator 505 corresponding to the previous sample and the subsequent sample can be expressed as a non-coherent combining value of correlation values between a receiving signal and a reference signal having a predetermined phase difference with respect to the receiving signal.

The loop filter 509 outputs a control voltage of a symbol timing controller 511 corresponding to the timing offset output by the early-late subtractor 507.

The symbol timing controller 511 controls a symbol timing according to the symbol timing offset output by the early-late subtractor by control of the loop filter 509. The symbol timing controller 511 can control the symbol timing by adjusting a phase of the input signal.

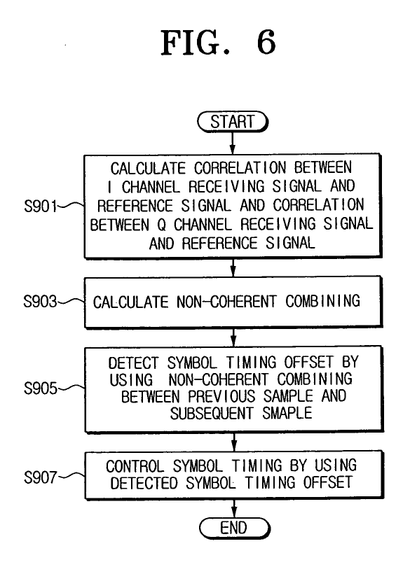

FIG. 6 is a flow chart illustrating a symbol timing recovery method usable with a VSB receiver according to an embodiment of the present general inventive concept.

Referring to FIG. 6, a first correlation value between an I channel receiving signal carrying transmission data information and a reference signal is calculated, and a second correlation value between the reference signal and a Q channel receiving signal is calculated (operation S901) for each sample of an input signal including the I and Q channel receiving signals. The Q channel receiving signal is in the shape of a Hilbert transform of the I channel signal and can be used to recover a carrier signal. Here, the reference signal acts as a reference for detecting a symbol time and may be at least one of a segment sync signal and a field sync signal. A FIR filter having a shape of an active correlator can be used to calculate a correlation between the I channel receiving signal and the reference signal and a correlation between the Q channel receiving signal and the reference signal.

A non-coherent combining value is then calculated for each sample based on the calculated first and second correlation values (operation S903). That is, after squaring each of the first correlation value and the second correlation value, the squared first and second correlation values are added to calculate the non-coherent combining value. This operation is expressed above in Equation 1. By squaring the first correlation value and the second correlation value, error of a carrier recovery is removed, so that the carrier recovery can be performed independently of the carrier recovery error. As a result, it is possible to eliminate the jitter due to the carrier recovery error. Also, a symbol timing recovery can be performed simultaneously with the carrier recovery.

A symbol timing offset is then detected by using the non-coherent combining values of the previous sample and the subsequent sample of samples of the input signal (operation S905). Here, by calculating a difference value between the non-coherent combining values in the previous sample and the subsequent sample, the symbol timing offset of a sample for detecting the symbol timing can be detected. The symbol timing offset can be calculated as expressed above in Equations 2 to 4:

The symbol timing is then controlled using the detected symbol timing offset (operation S907). The detected symbol timing offset can be used as a sampling clock of an analog to digital converter.

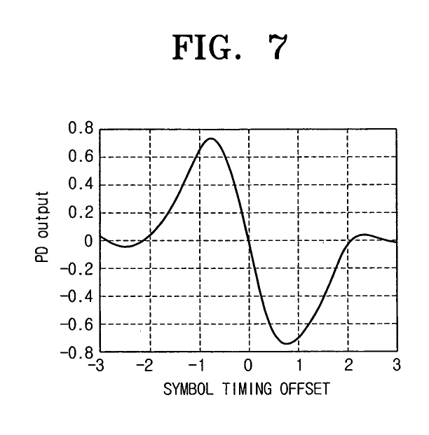

FIG. 7 is a diagram illustrating a characteristic curve of the early-late subtractor 507 of the symbol timing recovery apparatus of FIG. 5, in which a horizontal axis indicates the symbol timing offset, and a vertical axis indicates phase information being detected.

Referring to FIG. 7, when the symbol timing offset detected by the early-late subtractor 507 is not “0”, the symbol timing is controlled such that the symbol timing offset is to be “0” by the characteristic curve of the early-late subtractor 507 illustrated in FIG. 7. That is, the symbol timing controller 511 controls the symbol timing by adjusting the phase of the input signal based on the symbol timing offset according to the characteristic curve.

As described above, according to the present general inventive concept, by performing the symbol timing recovery using a non-coherent combining value of correlation values between an input signal and a reference signal, even if an upper band of the input signal is damaged, the symbol timing can be recovered.

Moreover, the symbol timing recovery is performed by using the non-coherent combining value of the correlation values between the input signal and the reference signal, such that the symbol timing recovery can be performed independently of carrier recovery error, thereby minimizing symbol timing jitter.

In addition, it is not necessary to perform carrier recovery before symbol timing recovery can be performed. That is, by using an asynchronous correlation value between the reference signal and each of an I channel receiving signal and a Q channel receiving signal, the symbol timing recovery can be performed simultaneously with the carrier recovery, and the symbol timing recovery does not need to be performed after the carrier recovery, thereby reducing time required for synchronism.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A symbol timing recovery apparatus usable with a VSB receiver, comprising:
a first correlator to calculate a first correlation value between an I channel receiving signal and a timing recovery reference signal;
a second correlator to calculate a second correlation value between a Q channel receiving signal having a phase difference of 90° with respect to the I channel receiving signal and the timing recovery reference signal;
a calculating unit to calculate a non-coherent combining value based on the first correlation value output from the first correlator and the second correlation value output from the second correlator;
an early-late subtractor to calculate a difference value between the non-coherent combining value of a previous sample and the non-coherent combining value of a subsequent sample in samples of the I channel receiving signal and the Q channel receiving signal, and to detect a symbol timing offset based on the calculated difference value; and
a symbol timing controller to control symbol timing based on the detected symbol timing offset.

2. The symbol timing recovery apparatus according to claim 1, wherein the timing recovery reference signal comprises at least one of a segment sync signal and a field sync signal.

3. The symbol timing recovery apparatus according to claim 1, wherein the first correlator and the second correlator each comprise a finite impulse filter.

4. The symbol timing recovery apparatus according to claim 1, wherein the calculating member calculates the non-coherent combining value based on the first correlation value and the second correlation value according to the following Equation:
$$S = {\vert {\sum }_{k = 0}^{M - 1} {r}_{I} ( k ) p ( k ) \vert}^{2} + {\vert {\sum }_{k = 0}^{M - 1} {r}_{Q} ( k ) p ( k ) \vert}^{2}$$
wherein S is the non-coherent combining value output by the calculator, M is a correlation length, r_{I}(k) is the I channel receiving signal, r_{Q}(k) is the Q channel receiving signal, and p(k) is the timing recovery reference signal.

5. The symbol timing recovery apparatus according to claim 1, wherein the early-late subtractor detects the symbol timing offset based on the following Equation:
$$\hat{τ} = {S}_{early} - {S}_{late} = \{ {\vert {\sum }_{k = 0}^{M - 1} {r}_{I} ( k ) p ( k + Δ ) \vert}^{2} + {\vert {\sum }_{k = 0}^{M - 1} {r}_{Q} ( k ) p ( k + Δ ) \vert}^{2} \} - \{ {\vert {\sum }_{k = 0}^{M - 1} {r}_{I} ( k ) p ( k - Δ ) \vert}^{2} + {\vert {\sum }_{k = 0}^{M - 1} {r}_{Q} ( k ) p ( k - Δ ) \vert}^{2} \} ,$$
wherein \hat{τ} is the detected symbol timing offset, S_{early} is the non-coherent combining value of the previous sample calculated by the calculating element, Sₗₐₜₑ is the non-coherent combining value of the subsequent sample calculated by the calculating element, M is a correlation length, r_{I}(k) is the I channel receiving signal, r_{Q}(k) is the Q channel receiving signal, p(k) is the timing recovery reference signal, and Δ is a phase difference between the I and Q channel receiving signals and the timing recovery reference signal.

6. The symbol timing recovery apparatus according to claim 5, wherein the phase difference between the I and Q channel receiving signals and the timing recovery reference signal is one of a half of a symbol period and the symbol period.

7. A symbol timing recovery apparatus usable with a VSB receiver, comprising:
a correlation unit to receive an input signal including an I channel signal and a Q channel signal having a phase difference of 90° with respect to the I channel signal, to calculate a first correlation value between the I channel signal and a reference signal and a second correlation value between the Q channel signal and the reference signal for each of a plurality of samples of the input signal;
a calculating unit to calculate a symbol timing offset corresponding to one of the plurality of samples, based on a difference between a non-coherent combination of the first and second correlation values of a previous sample and a non-coherent combination of the first and second correlation values of a next sample; and
a control unit to control symbol timing of the input signal based on the calculated symbol timing offset.

8. The symbol timing recovery apparatus according to claim 7, wherein the control unit controls the symbol timing of the input signal by adjusting a phase of the input signal based on the calculated symbol timing offset.

9. The symbol timing recovery apparatus according to 7, wherein the control unit comprises:
a symbol timing controller to control the symbol timing according to an input voltage; and
a loop filter to control the input voltage of the symbol timing controller based on the calculated symbol timing offset.

10. A symbol timing recovery method usable with a VSB receiver, comprising:
calculating a first correlation value between an I channel receiving signal and a timing recovery reference signal and a second correlation value between a Q channel receiving signal having a phase difference of 90° with respect to the I channel receiving signal and the timing recovery reference signal;
calculating a non-coherent combining value based on the first correlation value and the second correlation value;
calculating a difference value between the non-coherent combining value of a previous sample and the non-coherent combining value of a subsequent sample in samples of the I and Q channel receiving signals to detect a symbol timing offset; and
controlling symbol timing based on the symbol timing offset.

11. The method according to claim 10, wherein the reference signal comprises at least one of a segment sync signal and a field sync signal.

12. The method according to claim 10, wherein calculating of the first correlation value and the second correlation value comprises:
calculating the first and second correlation values using a FIR filter (Finite Impulse Response filter).

13. The method according to claim 10, wherein the calculating of the non-coherent combining value based on the first correlation value and the second correlation value comprises:
calculating the non-coherent combining value according to the following Equation:
$$S = {\vert {\sum }_{k = 0}^{M - 1} {r}_{I} ( k ) p ( k ) \vert}^{2} + {\vert {\sum }_{k = 0}^{M - 1} {r}_{Q} ( k ) p ( k ) \vert}^{2}$$
wherein S is the non-coherent combining value of the first and the second correlation values, M is a correlation length, r_{I}(k) is the I channel receiving signal, r_{Q}(k) is the Q channel receiving signal, and p(k) is the timing recovery reference signal.

14. The method according to claim 10, wherein calculating of the difference value between the non-coherent combining value of the previous sample and the non-coherent combining value of the subsequent sample to detect the symbol timing offset comprises:
detecting symbol timing offset is based on the following Equation:
$$\hat{τ} = {S}_{early} - {S}_{late} = \{ {\vert {\sum }_{k = 0}^{M - 1} {r}_{I} ( k ) p ( k + Δ ) \vert}^{2} + {\vert {\sum }_{k = 0}^{M - 1} {r}_{Q} ( k ) p ( k + Δ ) \vert}^{2} \} - \{ {\vert {\sum }_{k = 0}^{M - 1} {r}_{I} ( k ) p ( k - Δ ) \vert}^{2} + {\vert {\sum }_{k = 0}^{M - 1} {r}_{Q} ( k ) p ( k - Δ ) \vert}^{2} \}$$
wherein, \hat{τ} is the symbol timing offset, S_{early} is the non-coherent combining value of the previous sample, Sₗₐₜₑ is the non-coherent combining value of the subsequent sample, M is a correlation length, r_{I}(k) is the I channel receiving signal, r_{Q}(k) is the Q channel receiving signal, p(k) is the timing recovery reference signal, and Δ is a phase difference between the I and Q channel receiving signals and the timing recovery reference signal.

15. The method according to claim 14, wherein the phase difference between the I and Q channel receiving signals and the timing recovery reference signal is one of a half of a symbol period and the symbol period.

16. A symbol timing recovery method, comprising:
sampling an input signal including an I channel signal and a Q channel signal having a phase difference of 90° with respect to the I channel signal;
calculating a first correlation value between the I channel signal and a reference signal and a second correlation value between the Q channel signal and the reference value for each sample of the input signal;
calculating a symbol timing offset corresponding to one of the samples of the input signal based on a difference between a non-coherent combination of the first and second correlation values of a previous sample and a non-coherent combination of the first and second correlation values of a subsequent sample; and
controlling symbol timing based on the calculated symbol timing offset.

17. The method according to claim 16, wherein the controlling of the symbol timing comprises:
adjusting a phase of the input signal based on the calculated symbol timing offset.

18. The method according to claim 16, wherein the calculating of the symbol timing offset corresponding to one the samples of the input signal comprises:
calculating the non-coherent combination of the first and second correlation values of the previous sample by squaring each of the first and second correlation values of the previous sample and summing the squared first and second correlation values of the previous sample;
calculating the non-coherent combination of the first and second correlation values of the subsequent sample by squaring each of the first and second correlation values of the subsequent sample and summing the squared first and second correlation values of the subsequent sample; and
calculating a difference between the calculated non-coherent combination of the first and second correlation values of the previous sample and the calculated non-coherent combination of the first and second correlation values of the subsequent sample.

19. The method according to claim 16, wherein the calculating of the first correlation value between the I channel signal and the reference signal and a second correlation value between the Q channel signal and the reference value for each sample of the input signal comprises:
summing a plurality of correlation values between the I channel signal and the reference signal over a correlation length to determine the first correlation value for each sample; and
summing a plurality of correlation values between the Q channel signal and the reference signal over the correlation length to determine the second correlation value for each sample.

20. A symbol timing recovery apparatus, comprising:
a first correlator to calculate a first correlation value between an I channel receiving signal and a timing recovery reference signal;
a second correlator to calculate a correlation between a Q channel receiving signal having a phase difference of 90° with respect to the I channel receiving signal and the timing recovery reference signal;
a calculating member to calculate a non-coherent combining value based on the first correlation value output from the first correlator and the second correlation value output from the second correlator;
an early-late subtractor to calculate a difference value between the non-coherent combining value of a previous sample calculated by the calculating member and the non-coherent combining value of a subsequent sample calculated by the calculating member in samples of the I and Q channel receiving signals, and to detect a symbol timing offset based on the calculated difference value; and
a symbol timing controller to control symbol timing based on the symbol timing offset.
